(19) United States
(12) Patent Application Publication
(10) Pub. No.: US 2020/0090944 A1
(43) Pub. Date: Mar. 19, 2020

(54) SEMICONDUCTOR DEVICES

(71) Applicant: SAMSUNG ELECTRONICS CO., LTD., Suwon-si (KR)

(72) Inventors: Won-Jun LEE, Seoul (KR); Da-Hye SHIN, Cheonan-si (KR); Yil-Hyung LEE, Hwaseong-si (KR)

(21) Appl. No.: 16/375,092

(22) Filed: Apr. 4, 2019

(30) Foreign Application Priority Data
Sep. 13, 2018 (KR) 10-2018-0109473

(51) Int. Cl. H01L 21/311; H01L 21/02; H01L 21/768

(52) U.S. Cl. CPC H01L 21/31116; H01L 21/76843; H01L 21/02063

(57) ABSTRACT

A semiconductor device includes a conductive structure on a substrate, an etch stop layer on the conductive structure, an insulation layer on the etch stop layer, and a contact plug extending through the etch stop layer and the insulation layer and contacting the conductive structure. The contact plug may include first and second conductive pattern structures sequentially stacked and contacting with each other. A width of an upper surface of the first conductive pattern structure may be greater than that of a lower surface of the second conductive pattern structure. At least an upper portion of the first conductive pattern structure may have a sidewall not perpendicular but inclined to an upper surface of the substrate.

### CROSS-REFERENCE TO RELATED APPLICATION

Korean Patent Application No. 10-2018-0109473, filed on Sep. 13, 2018, in the Korean Intellectual Property Office, and entitled: “Semiconductor Devices,” is incorporated by reference herein in its entirety.

### BACKGROUND

### 1. Field

Embodiments relate to a semiconductor device.

### 2. Description of the Related Art

In manufacturing a semiconductor device, it is needed to form a contact plug contacting a conductive structure.

### SUMMARY

Embodiments are directed to a semiconductor device, including a conductive structure on a substrate, an etch stop layer on the conductive structure, an insulation layer on the etch stop layer, and a contact plug extending through the etch stop layer and the insulation layer and contacting the conductive structure. The contact plug may include first and second conductive pattern structures sequentially stacked and contacting with each other. A width of an upper surface of the first conductive pattern structure may be greater than that of a lower surface of the second conductive pattern structure. At least an upper portion of the first conductive pattern structure may have a sidewall not perpendicular but inclined to an upper surface of the substrate.

Embodiments are also directed to a semiconductor device, including a conductive structure on a substrate, an etch stop layer on the conductive structure, an insulation layer on the etch stop layer, and a contact plug extending through the etch stop layer and the insulation layer, extending in a vertical direction substantially perpendicular to an upper surface of the substrate, and contacting the conductive structure. The contact plug may include a protrusion portion at least at a central portion thereof in the vertical direction, the protrusion portion protruding in a horizontal direction substantially parallel to the upper surface of the substrate.

Embodiments are also directed to a semiconductor device, including an insulating interlayer on a substrate, the insulating interlayer containing a conductive line, an etch stop layer on the conductive line and the insulating interlayer, an insulation layer on the etch stop layer, a contact plug extending through the etch stop layer and the insulation layer and contacting the conductive line, a lower electrode on the contact plug, an MTJ structure on the lower electrode, and an upper electrode on the MTJ structure. The contact plug may include first and second conductive pattern structures. A width of an upper surface of the first conductive pattern structure may be greater than that of a lower surface of the second conductive pattern structure. At least an upper portion of the first conductive pattern structure may have a sidewall not perpendicular but inclined to an upper surface of the substrate.

### BRIEF DESCRIPTION OF THE DRAWINGS

Features will become apparent to those of skill in the art by describing in detail example embodiments with reference to the attached drawings in which:

FIGS. 1 to 7 illustrate cross-sectional views of stages of a method of manufacturing a semiconductor device in accordance with an example embodiment.

FIGS. 8 to 11 illustrate cross-sectional views of semiconductor devices in accordance with example embodiments.

FIGS. 12 to 23 illustrate cross-sectional views of stages of a method of manufacturing a semiconductor device in accordance with an example embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey example implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

A semiconductor device in accordance with an example embodiment will be described more fully hereinafter with reference to the accompanying drawings.

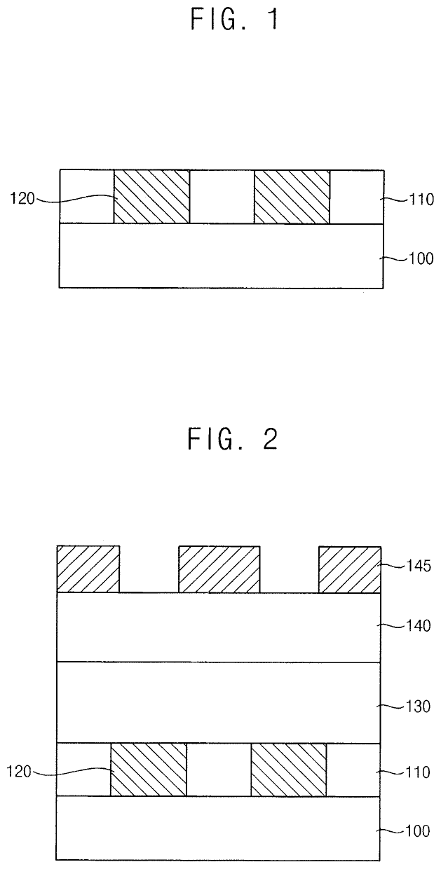

FIGS. 1 to 7 are cross-sectional views illustrating stages of a method of manufacturing a semiconductor device in accordance with an example embodiment.

Referring to FIG. 1, an insulating interlayer 110 may be formed on a substrate 100, and a conductive structure 120 may be formed through the insulating interlayer 110.

The substrate 100 may include, e.g., semiconductor materials, e.g., silicon, germanium, silicon-germanium, etc., or III-V compounds e.g., GaP, GaAs, GaSb, etc. In some embodiments, the substrate 100 may be a silicon-on-insulator (SOI) substrate or a germanium-on-insulator (GOI) substrate.

The insulating interlayer 110 may include, e.g., an oxide, e.g., silicon oxide, and the conductive structure 120 may include, e.g., a low resistance metal, e.g., aluminum (Al), copper (Cu), tantalum (Ta), etc., or a nitride thereof.

The conductive structure 120 may be formed by, e.g., forming a first opening extending through the insulating interlayer 110 to expose an upper surface of the substrate 100, forming a first conductive layer on the exposed upper surface of the substrate 100 and an upper surface of the insulating interlayer 110 to fill the first opening, and planarizing the first conductive layer until the upper surface of the insulating interlayer 110 is exposed.

The planarization process may be performed by, e.g., a CMP process and/or an etch back process.

The conductive structure 120 may be formed in a single number or plural numbers.

Referring to FIG. 2, an etch stop layer 130 and an insulation layer 140 may be sequentially formed on the insulating interlayer 110 and the conductive structure 120, and a first etching mask 145 may be formed on the insulation layer 140.

The etch stop layer 130 may include, e.g., silicon nitride (SiNₓ) or silicon carbonitride (SiCN), and the insulation layer 140 may include, e.g., silicon oxide (SiO₂).

The first etching mask 145 may include, e.g., a photoresist pattern, silicon-on-hardmask (SOH), an amorphous carbon layer (ACL), etc.

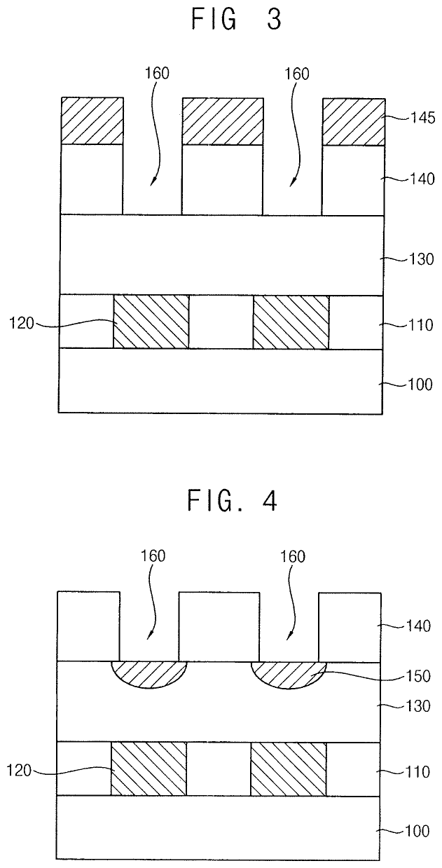

Referring to FIG. 3, a portion of the insulation layer 140 may be removed by a first etching process using the first etching mask 145, and a second opening 160 may be formed to expose an upper surface of the etch stop layer 130.

The first etching process may be performed by, e.g., a dry etching process using a fluorine-based gas such as hexafluorobutyne (C₄F₆), octafluorocyclobutane (C₄F₈), or the like.

The second opening 160 may have a sidewall substantially perpendicular to the upper surface of the substrate 100.

Referring to FIG. 4, an ashing process and/or a stripping process may be performed to remove an etching residue generated by the first etching process.

The ashing process and/or the stripping process may use e.g., oxygen (O₂) plasma, and an exposed upper portion of the etch stop layer 130 may be reacted with oxygen plasma to form a denatured layer 150. The denatured layer 150 may include e.g., silicon oxynitride (SiON) or silicon oxycarbonitride (SiOCN).

The denatured layer 150 may be formed on the upper portion of the etch stop layer 130 exposed by the second opening 160, and may be formed on a portion of the etch stop layer 130 adjacent thereto.

During the ashing process and/or the stripping process, the first etching mask 145 may be partially or totally removed.

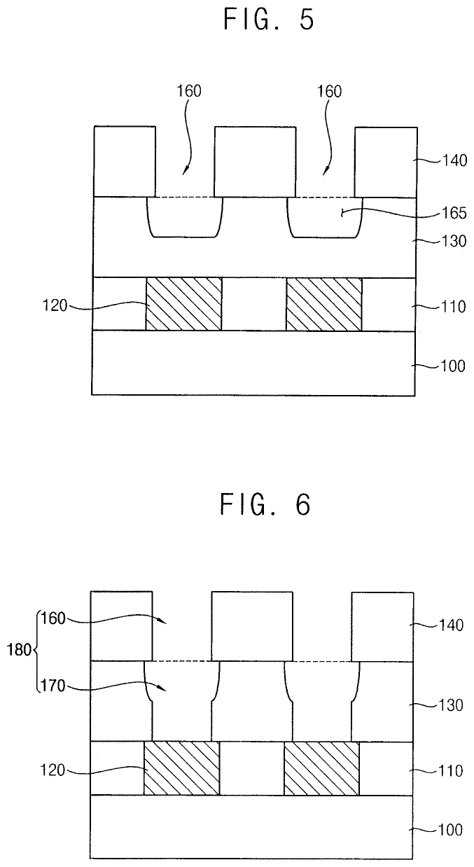

Referring to FIG. 5, a cleaning process may be performed to remove the denatured layer 150, and thus a trench 165 may be formed at the upper portion of the etch stop layer 130 to be connected with the second opening 160.

The cleaning process may be performed by, e.g., an isotropic wet etching process using, e.g., a hydrogen fluoride (HF) aqueous solution. The aqueous hydrogen fluoride (HF) solution may have a concentration of, e.g., about 1% to about 5%. In another implementation, the cleaning process may be performed by an isotropic dry etching process using, e.g., hydrogen fluoride (HF) alone or a mixture of ammonia (NH₃) and hydrogen fluoride (HF).

The trench 165 may have a sidewall inclined from the perpendicular relative to the upper surface of the substrate 100, and an upper portion of the trench 165 may have a width greater than that of a lower portion of the second opening 160.

Referring to FIG. 6, a portion of the etch stop layer 130 under the trench 165 may be removed by, e.g., a second etching process using a second mask (which may cover an upper surface of the insulation layer 140) as an etching mask, and the trench 165 may extend in the vertical direction to form a third opening 170 exposing an upper surface of the conductive structure 120.

As a result, the second opening 160 and the third opening 170 may be connected with each other to form a contact hole 180.

The second etching process may be performed by e.g., a dry etching process using a fluorine-based gas such as hexafluorobutyne (C₄F₆), octafluorocyclobutane (C₄F₈), or the like.

An upper portion of the third opening 170 may have a width greater than that of the lower portion of the second opening 160, and the upper portion of the third opening 170 may have a sidewall inclined from the perpendicular relative to the upper surface of the substrate 100. A lower portion of the third opening 170 may have a sidewall substantially perpendicular to the upper surface of the substrate 100.

As described above, when the contact hole 180 is formed, the cleaning process may be performed before the second etching process to remove the denatured layer 150 at the upper portion of etch stop layer 130. Accordingly, when the second etching process is performed, the etch stop layer 130 may be easily removed, and the third opening 170 may efficiently expose the upper surface of the conductive structure 120.

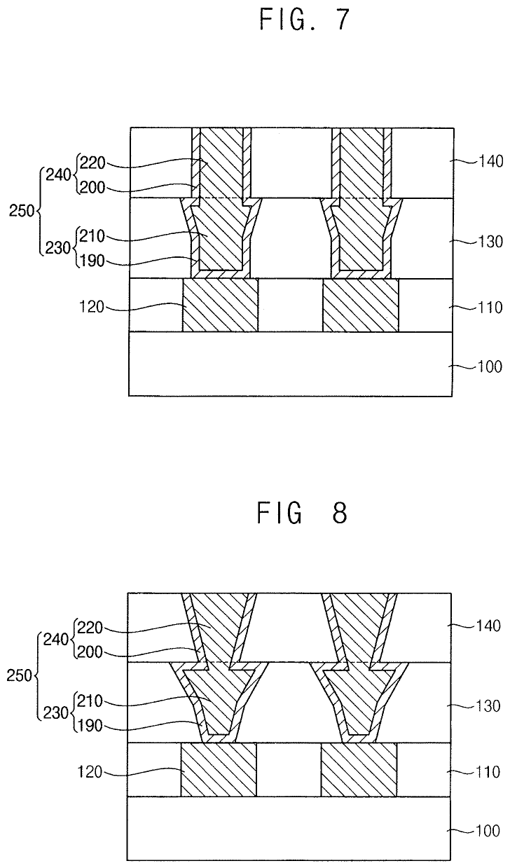

Referring to FIG. 7, a contact plug 250 may be formed to fill the contact hole 180.

A barrier layer may be formed on a sidewall of the contact hole 180, the exposed upper surface of the conductive structure 120, and the upper surface of the insulation layer 140. A second conductive layer may be formed on the barrier layer to fill a remaining portion of the contact hole 180. The second conductive layer and the barrier layer may be planarized until the upper surface of the insulation layer 140 is exposed to form the contact plug 250 in the contact hole 180.

The contact plug 250 may include first and second conductive pattern structures 230 and 240, which may be stacked in the vertical direction to contact each other and may fill the third and second openings 170 and 160, respectively. The first conductive pattern structure 230 may include a first conductive pattern 210 and a first barrier pattern 190 covering a sidewall and a lower surface of the first conductive pattern 210. The second conductive pattern structure 240 may include a second conductive pattern 220 and a second barrier pattern 200 covering a sidewall of the second conductive pattern 220.

An upper surface of the first conductive pattern structure 230 may have a width greater than that of a lower surface of the second conductive pattern structure 240, and an upper portion of the first conductive pattern structure 230 may have a sidewall not perpendicular but inclined to the upper surface of the substrate 100. A lower portion of the first conductive pattern structure 230 may have a sidewall substantially perpendicular to the upper surface of the substrate 100. The second conductive pattern structure 240 may also have a sidewall substantially perpendicular to the upper surface of the substrate 100.

As described above, due to the shape of the sidewall of the first conductive pattern structure 230, the contact plug 250 may have a protrusion portion, which may protrude in a horizontal direction substantially parallel to the upper surface of the substrate 100 at a central portion in the vertical direction of the contact plug 250.

The first and second conductive patterns 210 and 220 may include, e.g., a metal, e.g., copper, tungsten, aluminum, etc., and the first and second barrier patterns 190 and 200 may include, e.g., a metal, e.g., titanium, tantalum, etc., or a metal nitride, e.g., titanium nitride, tantalum nitride, etc.

Upper wirings connected to the contact plug 250 may be further formed to complete the fabrication of the semiconductor device.

FIGS. 8 to 11 are cross-sectional views illustrating semiconductor devices in accordance with example embodiments. The semiconductor devices may be substantially the same as or similar to the semiconductor device described in FIG. 7, except for the shape of contact plugs. Accordingly, a repeated description of some details thereof may be omitted.

In a method of manufacturing a semiconductor device in accordance with an example embodiment, in a process for forming a contact hole that extends through a structure including an etch stop layer and an insulation layer to expose a conductive structure thereunder, a cleaning process may be further performed to remove a denatured layer that may be formed after a first etching process for etching the insulation layer, and thus the contact hole may effectively expose the conductive structure. In detail, referring to FIG. 8, a lower sidewall of the first conductive pattern structure 230 and a sidewall of the second conductive pattern structure 240 may be inclined to the upper surface of the substrate 100, which may be implemented when the second opening 160 and the lower portion of the third opening 170 that are formed by the first and second etching processes, respectively, described in FIGS. 3 and 6 have sidewalls inclined to the upper surface of the substrate 100.

Even if the lower sidewall of the first conductive pattern structure 230 and the sidewall of the second conductive pattern structure 240 have inclined sidewalls, respectively, first and second slopes of the lower sidewall of the first conductive pattern structure 230 and the sidewall of the second conductive pattern structure 240, respectively, with respect to the upper surface of the substrate 100 may be smaller than a third slope of an upper sidewall of the first conductive pattern structure 230 with respect to the upper surface of the substrate 100. In one embodiment, the first and second slopes may be substantially the same as each other.

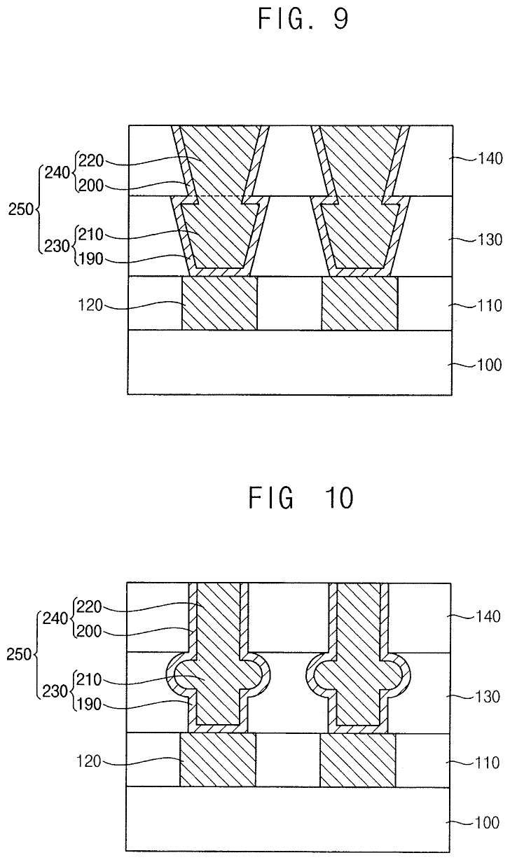

Referring to FIG. 9, an upper sidewall and a lower sidewall of the first conductive pattern structure 230 may have substantially the same slope as each other, which may be implemented when the denatured layer 150 that may be formed during the aching process and/or the stripping process described in FIG. 4 has substantially the same thickness as the etch stop layer 130, or when the etch stop layer 130 under the denatured layer 150 is removed together with the denatured layer 150 during the cleaning process described in FIG. 5 so that the trench 165 exposes the upper surface of the conductive structure 120. In this case, the second etching process described in FIG. 6 may not be performed.

The sidewall of the second conductive pattern structure 240 may be perpendicular, or may be inclined to the upper surface of the substrate 100, as shown in FIG. 9. The second slope of the sidewall of the second conductive pattern structure 240 may be substantially the same as or smaller than the first slope of the first conductive pattern structure 230.

Referring to FIG. 10, an absolute value of the slope of the upper sidewall of the first conductive pattern structure 230 may gradually increase and then decrease from an upper portion toward a lower portion thereof, as compared to that of the upper sidewall of the first conductive pattern structure 230 shown in FIG. 7.

The shape of the upper sidewall of the first conductive pattern structure 230 may be caused by the shape of the denatured layer 150 formed during the ashing process and/or the stripping process described in FIG. 4, or when a portion of the denatured layer 150 adjacent to the insulation layer 140 thereon is not entirely removed during the cleaning process described in FIG. 5.

Accordingly, the upper sidewall of the first conductive pattern structure 230 may have a smoothly curved shape. Thus, a protrusion portion at a central portion of the contact plug 250 in the vertical direction may have the smoothly curved shape. Thus, the central portion of the contact plug 250 may have a convex shape.

Referring to FIG. 11, the contact plug 250 may include a protrusion portion having a smoothly curved shape similar to that of the contact plug 250 described in FIG. 10, however, the protrusion portion may be formed not only at the central portion thereof, but also at a lower portion of the contact plug 250.

The shape of the contact plug 250 may be formed when the denatured layer 150 is formed to have substantially the same thickness as the etch stop layer 130, or when the etch stop layer 130 under the denatured layer 150 is removed together with the denatured layer 150 during the cleaning process for removing the denatured layer 150.

Accordingly, an upper portion of the contact plug 250 may have a uniform width, while the lower portion may have a width gradually increasing and then decreasing downwardly. In another implementation, the upper portion of the contact plug 250 may have a gradually decreasing width downwardly, which may be similar to that of the contact plug 250 described in FIG. 8.

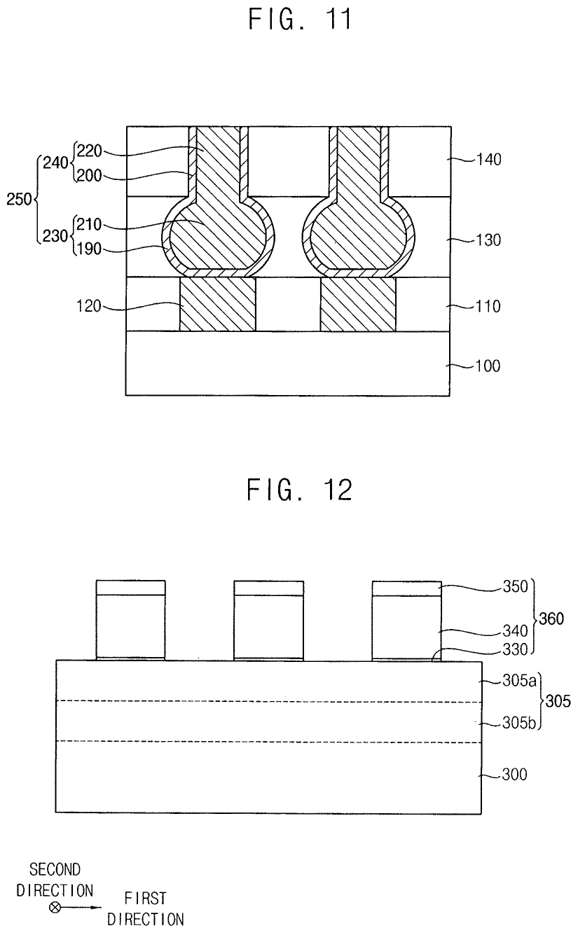

FIGS. 12 to 23 are cross-sectional views illustrating stages of a method of manufacturing a semiconductor device in accordance with an example embodiment.

This method of manufacturing the semiconductor device may include processes substantially the same as or similar to the processes described in FIGS. 1 to 7. Accordingly, like reference numerals refer to like elements, and a repeated description of some details thereof may be omitted.

Referring to FIG. 12, an upper portion of a substrate 300 may be partially etched to form a first recess, an active fin 305 may be formed on the substrate 300, and an isolation pattern may be formed to cover a lower sidewall of the active fin 305.

The active fin 305 may include a lower active pattern 305b of which a sidewall may be covered by the isolation pattern, and an upper active pattern 305a protruding from an upper portion of the isolation pattern. In example embodiments, the active fin 305 may extend in a first direction substantially parallel to an upper surface of the substrate 300, and a plurality of active fins 305 may be formed in a second direction substantially parallel to the upper surface of the substrate 300 and intersecting with the first direction.

A dummy gate structure 360 may be formed on the active fin 305. For example, after sequentially forming a dummy gate insulation layer, a dummy gate electrode layer and a dummy gate mask layer on the active fin 305 of the substrate 300 and the isolation pattern, the dummy gate mask layer may be patterned to form a dummy gate mask 350, and the dummy gate electrode layer and the dummy gate insulation layer under the dummy gate mask 350 may be sequentially etched using the dummy gate mask 350 as an etching mask to form a dummy gate electrode 340 and a dummy gate insulation pattern 330, respectively. Accordingly, the dummy gate structure 360 including the dummy gate insulation pattern 330, the dummy gate electrode 340 and the dummy gate mask 350 sequentially stacked on the active fin 305 and the isolation pattern may be formed. In an example embodiment, the dummy gate structure 360 may extend in the second direction, and a plurality of dummy gate structures 360 may be formed in the first direction.

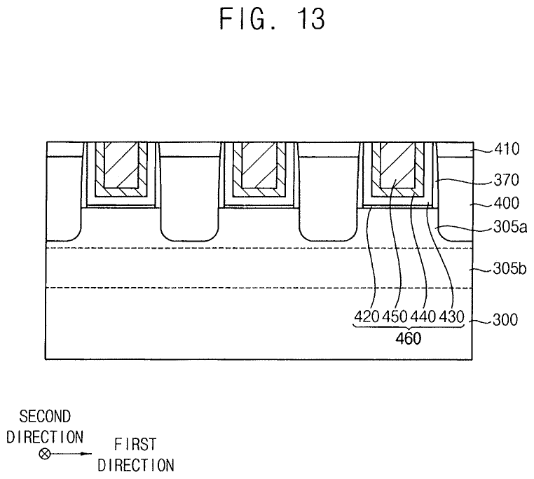

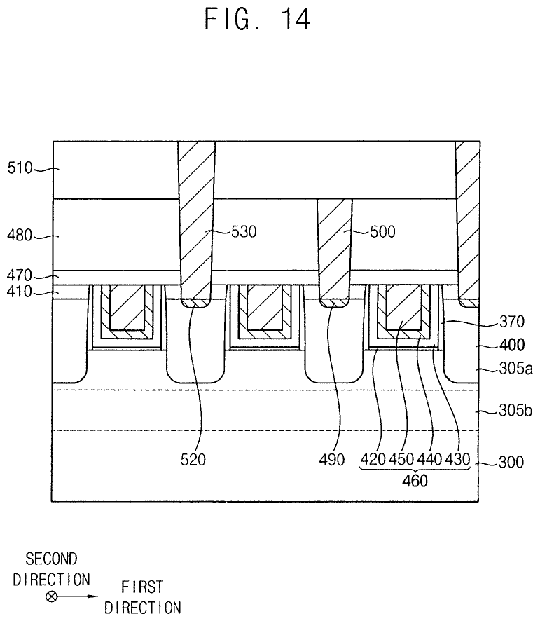

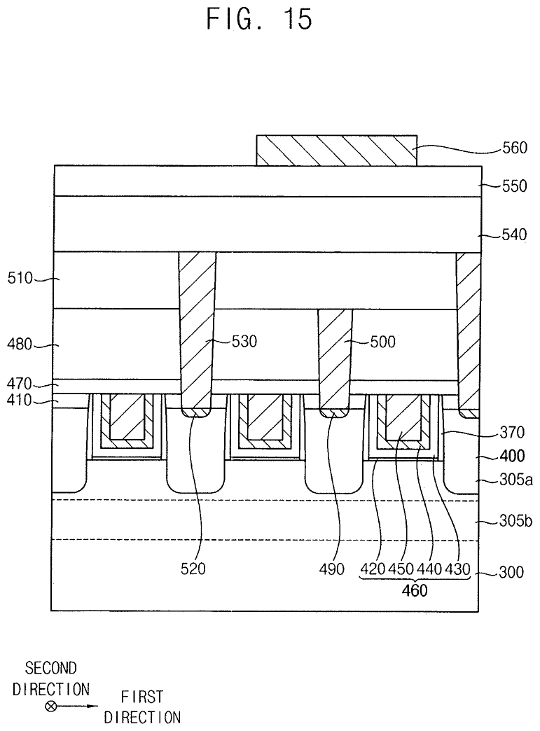

Referring to FIG. 13, after forming a gate spacer 370 on a sidewall of the dummy gate structure 360, a source/drain layer 400 may be formed on the active fin 305 adjacent to the gate spacer 370, and a first insulating interlayer 410 may be formed on the active fin 305 and the isolation pattern to cover the source/drain layer 400 and a sidewall of the gate spacer 370.

The gate spacer 370 may be formed by forming a spacer layer on the active fin 305 and the isolation pattern to cover the dummy gate structure 360, and anisotropically etching the spacer layer.

The source/drain layer 400 may be formed by removing the upper portion of the active fin 305 through a dry etching process using the gate spacer 370 and the dummy gate structure 360 as an etching mask form a second recess, and filling the second recess. In an example embodiment, the source/drain layer 400 may be formed by performing a selective epitaxial growth (SEG) process using an exposed upper surface of the active fin 305 as a seed.

The first insulating interlayer 410 may be formed on the substrate 300 to cover the dummy gate structure 360, the gate spacer 370 and the source/drain layer 400, and an upper portion of the first insulating interlayer 410 may be planarized until an upper surface of the dummy gate electrode 340 of the dummy gate structure 360 is exposed.

The exposed dummy gate electrode 340 and the dummy gate insulation pattern 330 thereunder may be removed to form a fourth opening exposing an inner sidewall of the gate spacer 370 and the upper surface of the active fin 305, and a gate structure 460 may be formed to fill the fourth opening.

The gate structure 460 may be formed by, e.g., performing following processes. First, a thermal oxidation process may be performed on the upper surface of the active fin 305 exposed by the fourth opening to form an interface pattern 420 a gate insulation layer and a work function control layer may be sequentially formed on the interface pattern 420, the isolation pattern, gate spacer 370 and the first insulating interlayer 410 and a gate electrode layer may be formed on the work function control layer to sufficiently fill a remaining portion of the fourth opening.

Then, the gate electrode layer, the work function control layer and the gate insulation layer may be planarized until an upper surface of the first insulating interlayer is exposed, so that a gate insulation pattern 430 and a work function control pattern 440 sequentially stacked on an upper surface of the interface pattern 420, an upper surface of the isolation pattern and the inner sidewall of the gate spacer 370 may be formed, and a gate electrode 450 may be formed on the work function control pattern 440 to fill the remaining portion of the fourth opening. Accordingly, a lower surface and a sidewall of the gate electrode 450 may be covered by the work function control pattern 440.

The interface pattern 420, the gate insulation pattern 430, the work function control pattern 440, and the gate electrode 450, sequentially stacked, may form the gate structure 460. The gate structure 460 may form a transistor together with the source/drain layer 400. The transistor may form a PMOS transistor or an NMOS transistor according to the conductivity type of the source/drain layer 400.

Referring to FIG. 14, a capping layer 470 and a second insulating interlayer 480 may be sequentially formed on the first, insulating interlayer 410, the gate structure 460, and the gate spacer 370, and a source line 500 may be formed to extend through the first insulating interlayer 410, the capping layer 470, and the second insulating interlayer 480 to contact an upper surface of a portion of the source/drain layers 400 (hereinafter referred to as a first source/drain layer).

Before forming the source line 500 a first metal silicide pattern 490 may be further formed on an upper portion of the first source/drain layer. For example, a fifth opening may be formed to extend through the first insulating interlayer 410, the capping layer 470, and the second insulating interlayer 480 to expose an upper surface of the first source/drain layer. A first metal layer may be formed on the upper surface of the first source/drain layer, a sidewall of the fifth opening, and an upper surface of the second insulating interlayer. A heat treatment process may be performed to form the first metal silicide pattern 490 on the upper portion of the first source/drain layer.

The source line 500 may include a metal, a metal nitride, and/or doped polysilicon, and may have a structure of a conductive pattern and a barrier pattern covering a lower surface and a sidewall thereof. In an example embodiment, the source line 500 may extend in the second direction by a given length, and a plurality of source lines 500 may be formed in the first direction.

After forming a third insulating interlayer 510 on the second insulating interlayer 480 and the source line 500, a first contact plug 530 may be formed to extend through the first insulating interlayer 410, the capping layer 470, the second insulating interlayer 480, and the third insulating interlayer 510 to contact an upper surface of a portion of the source/drain layers 400 (hereinafter referred to as a second source/drain layer). The first contact plug 530 may correspond to the conductive structure 120 in the method of manufacturing the semiconductor device described in FIGS. 1 to 7.

A second metal silicide pattern 520 may be further formed between the first contact plug 530 and the second source/drain layer. The first contact plug 530 may also have a structure of a conductive pattern and a barrier pattern covering a lower surface and a sidewall thereof.

Referring to FIG. 15, after sequentially forming a first etch stop layer 540 and a fourth insulating interlayer 550 on the third insulating interlayer 510 and the first contact plug 530, a first etching mask 560 may be formed on the fourth insulating interlayer 550.

In example embodiments, the first etch stop layer 540 may include a silicon nitride (SiNₓ) or a silicon carbonitride (SiCN).

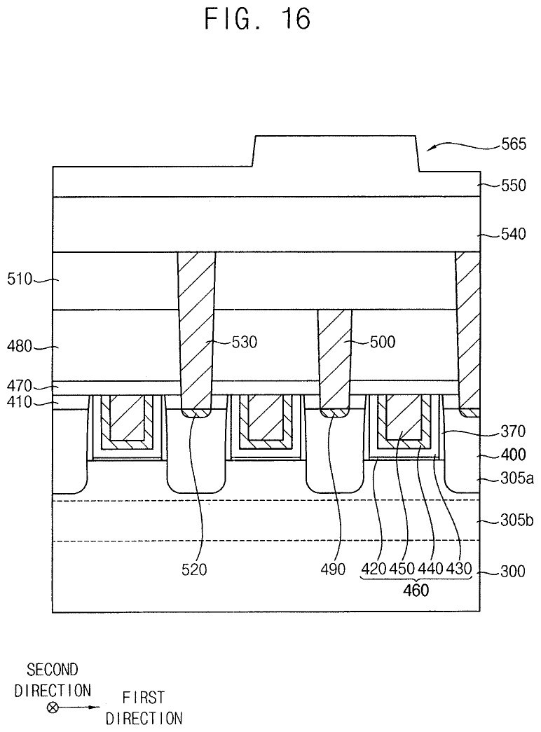

Referring to FIG. 16, an upper portion of the fourth insulating interlayer 550 may be partially removed by a first etching process using the first etching mask 560 to form a first trench 565.

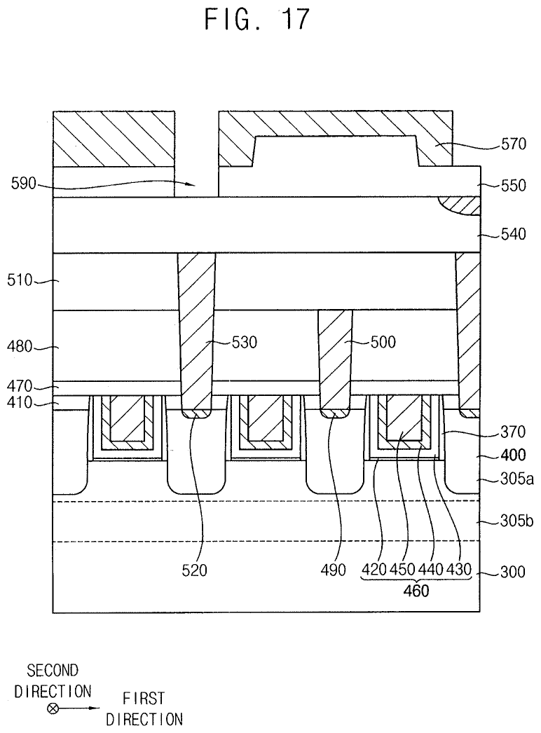

Referring to FIG. 17, after forming a second etching mask 570 to cover a portion of the fourth insulating interlayer 550, a remaining portion of the fourth insulating interlayer 550 may be removed by a second etching process using the second etching mask to form a first opening 590 exposing a portion of the first etch stop layer 540.

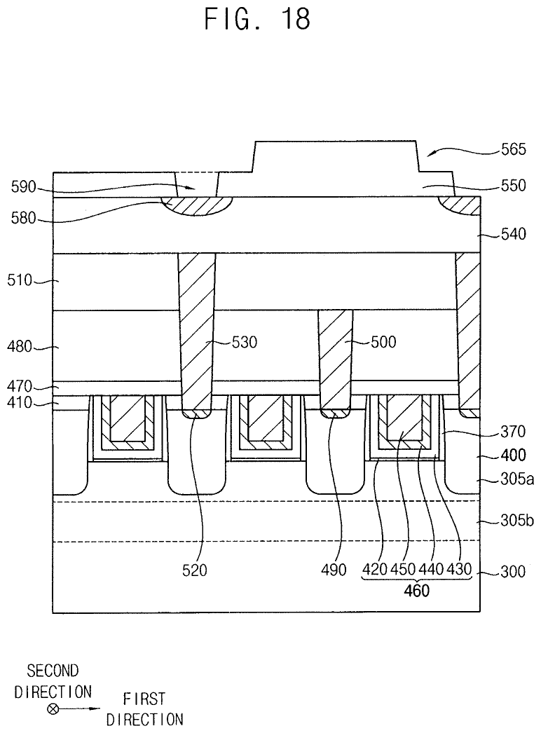

Referring to FIG. 18, an ashing process and/or a stripping process may be performed to remove an etching residue generated by the second etching process. Thus, a denatured layer 580 may be formed on at upper portion of the exposed first etch stop layer 540.

In an example embodiment, the ashing process and/or the stripping process may use oxygen (O₂) plasma, and thus the denatured layer 580 may include, e.g., silicon oxynitride (SiON) or silicon oxycarbonitride (SiOCN).

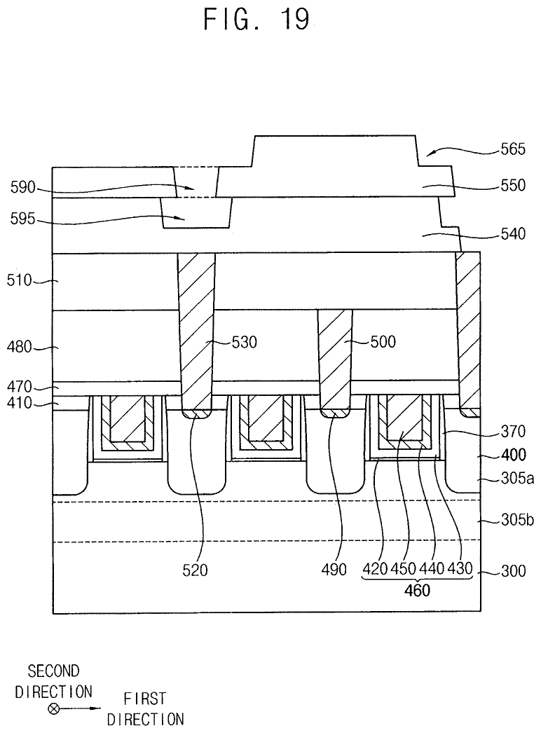

Referring to FIG. 19, a cleaning process may be performed to remove the denatured layer 580. Thus, the upper portion of the first etch stop layer 540 may be removed to form a second trench 595.

In an example embodiment, the second trench 595 may have a sidewall not perpendicular but inclined to the upper surface of the substrate 300, and a width of an upper portion of the second trench 595 may be greater than that of a lower portion of the first opening 590.

In an example embodiment, the cleaning process may be performed by an isotropic wet etching process using a hydrogen fluoride (HF) aqueous solution. The aqueous hydrogen fluoride (HF) solution may have a concentration of about 1% to about 5%. In another implementation, the cleaning process may be performed by an isotropic dry etching process using hydrogen fluoride (HF) alone, or a mixture of ammonia (NH₃) and hydrogen fluoride (HF).

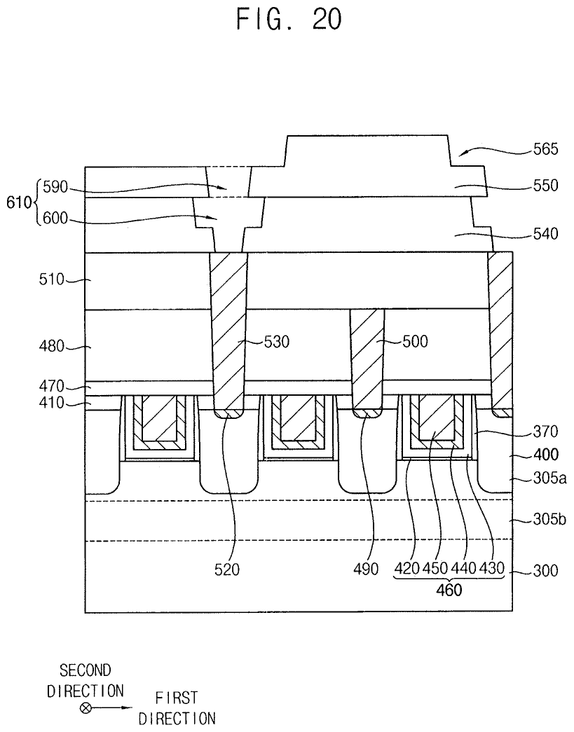

Referring to FIG. 20, a portion of the first etch stop layer 540 under the second trench 595 may be removed by a third etching process using the third etching mask, and the second trench 595 may be enlarged downwardly. The enlarged second trench 595 may be referred to as a second opening 600 exposing an upper surface of the first contact plug 530.

The first and second openings 590 and 600 may be connected with each other to form a first contact hole 610.

In an example embodiment, an upper portion of the second opening 600 may have a sidewall not perpendicular but inclined to the upper surface of the substrate 300, and a width of the upper portion of the second opening 600 may be greater than that of the lower portion of the first opening 590.

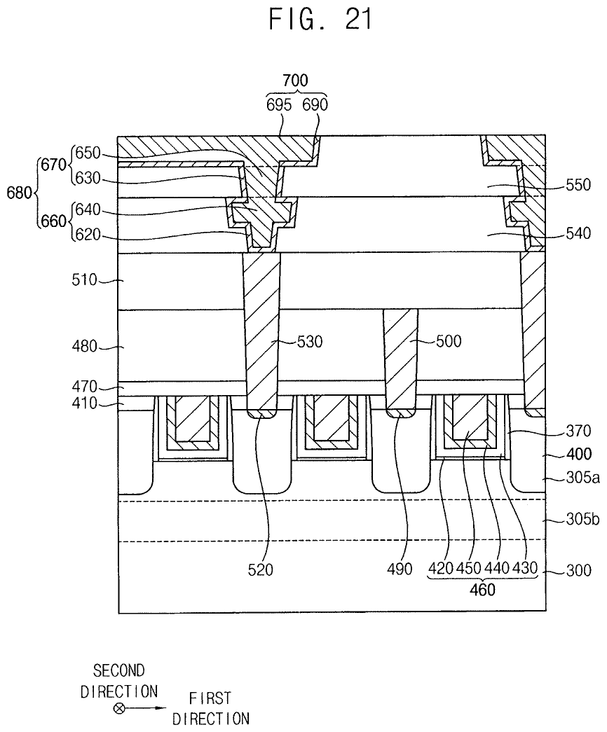

Referring to FIG. 21, a second contact plug 680 and a first wiring 700 may be formed to fill the first contact hole 610 and the first trench 565.

The second contact plug 680 may include first and second conductive pattern structures 660 and 670 sequentially stacked and contacting each other. The first conductive pattern structure 660 may include a third conductive pattern 640 and a third barrier pattern 620 covering a sidewall and a lower surface of the third conductive pattern 640. The second conductive pattern structure 670 may include a fourth conductive pattern 650 and a fourth barrier pattern 630 covering a sidewall of the fourth conductive pattern 650.

In an example embodiment, a width of an upper surface of the first conductive pattern structure 660 may be greater than that of a lower surface of the second conductive pattern structure 670, and an upper portion of the first conductive pattern structure 660 may have a sidewall not perpendicular but inclined to the upper surface of the substrate 300. A lower portion of the first conductive pattern structure 660 and the second conductive pattern structure 670 may have sidewalls substantially perpendicular to the upper surface of the substrate 300. In another implementation, the lower portion of the first conductive pattern structure 660 and the second conductive pattern structure 670 may have sidewalls not perpendicular but inclined to the upper surface of the substrate 300.

The first wiring 700 may include a fifth conductive pattern 695 and a fifth barrier pattern 690 covering a sidewall and a portion of a lower surface of the fifth conductive pattern 695, and may contact the second contact plug 680 thereunder.

In an example embodiment, the first wiring 700 and the second contact plug 680 may be simultaneously formed by a dual damascene process. The first wiring 700 and the second contact plug 680 may be each formed by a single damascene process.

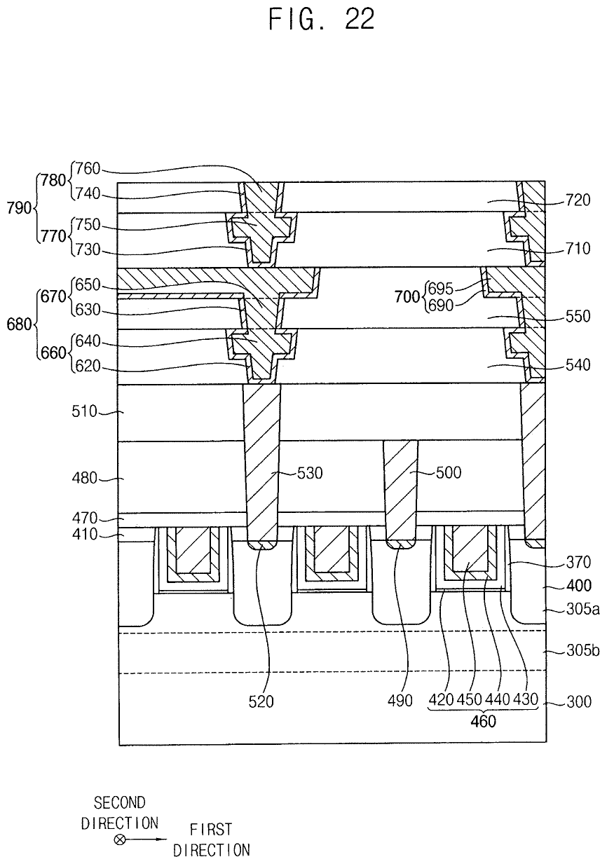

Referring to FIG. 22, a second etch stop layer 710 and a fifth insulating interlayer 720 may be sequentially formed on the fourth insulating interlayer 550 and the first wiring 700, and a third contact plug 790 extending through the second etch stop layer 710 and the fifth insulating interlayer 720 may be formed.

The third contact plug 790 may be formed by a process similar to the process for forming the second contact plug 680, and may have a shape similar to that of the second contact plug 680. Accordingly, the third contact plug 790 may include third and fourth conductive pattern structures 770 and 780 sequentially stacked. The third conductive pattern structure 770 may include a sixth conductive pattern 750 and a sixth barrier pattern 730 covering a sidewall and a lower surface of the sixth conductive pattern 750. The fourth conductive pattern structure 780 may include a seventh conductive pattern 760 and a seventh barrier pattern 740 covering a sidewall of the seventh conductive pattern 760.

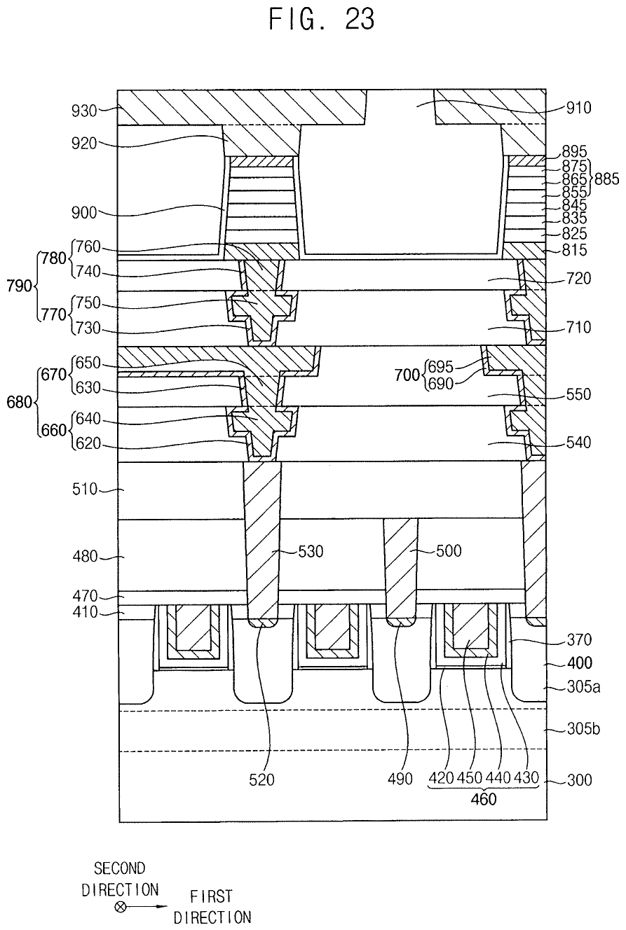

Referring to FIG. 23, a memory unit including a lower electrode 815, a blocking pattern 825 an adhesive pattern 835, a seed pattern 845, an MTJ structure 885, and an upper electrode 895 sequentially stacked, may be formed on the third contact plug 790. The MTJ structure 885 may include a fixed layer pattern 855, a tunnel barrier pattern 865, and a free layer pattern 875 sequentially stacked.

In an example embodiment, a lower electrode layer, a blocking layer, an adhesive layer, a seed layer, an magnetic tunnel junction (MTJ) structure layer, and an upper electrode layer may be sequentially formed on the third contact plug 790. The MTJ structure layer may include a fixed layer, a tunnel barrier layer, and a free layer, sequentially stacked. The upper electrode layer, the MTJ structure layer, the seed layer, the adhesive layer, the blocking layer, and the lower electrode layer may be etching by a etching process to form the memory unit including the lower electrode 815, the blocking pattern 825, the adhesive pattern 835, the seed pattern 845, the MTJ structure 885, and the upper electrode 895 sequentially stacked on the third contact plug 790.

The lower electrode 815 may include a metal nitride, e.g., titanium nitride, tantalum nitride, etc. The blocking pattern 825 may include a metal boride, e.g., tantalum boride, titanium boride, e.g., a metal boronitride, e.g., tantalum boronitride, titanium boronitride, e.g., or a metal compound, e.g., tantalum carbon fluoroborate (CFBTa). The adhesive pattern 835 may include a metal, e.g., tantalum, titanium, etc. The seed pattern 845 may include a metal, e.g., ruthenium (Ru), rhenium (Re), etc.

The fixed layer pattern 855 may include a ferromagnetic material, e.g., cobalt, platinum, iron, nickel, etc. In an example embodiment, the fixed layer pattern 855 may include an alloy of cobalt and platinum, i.e., CoPt, or a multi-layered structure including a cobalt layer and a platinum layer alternately stacked. The tunnel barrier pattern 865 may include, e.g., magnesium oxide or aluminum oxide. The free layer pattern 875 may include a ferromagnetic material, e.g., cobalt, platinum, iron, nickel, etc.

The MTJ structure layer may include a free layer, a tunnel barrier layer, and a fixed layer sequentially stacked. At least one of the fixed layer, the tunnel barrier layer and the free layer may be formed at a plurality of levels.

The upper electrode 895 may include a metal, e.g., titanium, tantalum, etc., and/or a metal nitride, e.g., titanium nitride, tantalum nitride, etc.

A protection layer 900 may be formed to cover the memory unit. A sixth insulating interlayer 910 may be formed on the protection layer 900. A via 920 and a second wiring 930 sequentially stacked may be formed to extend through an upper portion of the sixth insulating interlayer 910.

In an example embodiment, the second wiring 930 and the via 920 may be simultaneously formed by a dual damascene process. In another implementation, the second wiring 930 and the via 920 may be each formed by a single damascene process. In an example embodiment, the via 920 may be formed by processes substantially the same as or similar to the processes for forming the second and third contact plugs 680, 790, and thus may include a protrusion portion at a central portion of the via 920.

Upper wirings connected with the sixth insulating interlayer 910 and the second via 920 may be further formed to complete the fabrication of the semiconductor device.

The above semiconductor device may be applied to various types of memory devices and systems including contact plugs. For example, the semiconductor may be applied to logic devices such as central processing units (CPUs), main processing units (MPUs), or application processors (APs), or the like, including contact plugs. Additionally, the semiconductor device may be applied to volatile memory devices such as DRAM devices or SRAM devices, or the like, or non-volatile memory devices such as flash memory devices, PRAM devices, MRAM devices, RRAM devices, or the like, including contact plugs.

By way of summation and review, in a general process for forming a contact plug extending through an etch stop layer and an insulation layer sequentially stacked on a conductive structure to contact an upper surface of the conductive structure the insulation layer may be etched by a first etching process using a first etching mask to expose an upper surface of the etch stop layer, the first etching mask may be removed, the etch stop layer may be etched by a second etching process using a second etching mask to form a contact hole exposing the upper surface of the conductive structure. However, the contact hole may not expose the upper surface of the conductive structure, and thus the contact plug may not contact the upper surface of the conductive structure.

As described above, embodiments relate to a semiconductor device including a contact plug. Example embodiments may provide a semiconductor device having improved characteristics.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
a conductive structure on a substrate;
an etch stop layer on the conductive structure;
an insulation layer on the etch stop layer; and
a contact plug extending through the etch stop layer and the insulation layer and contacting the conductive structure,
wherein the contact plug includes first and second conductive pattern structures sequentially stacked and contacting each other, a width of an upper surface of the first conductive pattern structure is greater than that of a lower surface of the second conductive pattern structure, and at least an upper portion of the first conductive pattern structure has a sidewall not perpendicular but inclined to an upper surface of the substrate.

2. The semiconductor device as claimed in claim 1, wherein the width of the upper surface of the first conductive structure is greater than a width of a lower surface of the first conductive pattern structure.

3. The semiconductor device as claimed in claim 1, wherein a lower portion of the first conductive pattern structure includes a sidewall substantially perpendicular to the upper surface of the substrate.

4. The semiconductor device as claimed in claim 1, wherein a lower portion of the first conductive pattern structure includes a sidewall of which a slope is substantially the same as that of the upper portion of the first conductive pattern structure.

5. The semiconductor device as claimed in claim 1, wherein the sidewall of the upper portion of the first conductive pattern structure has a first slope with respect to the upper surface of the substrate, and
wherein a sidewall of a lower portion of the first conductive pattern structure has a second slope greater than the first slope with respect to the upper surface of the substrate.

6. The semiconductor device as claimed in claim 1, wherein the second conductive pattern structure has a sidewall substantially perpendicular to the upper surface of the substrate.

7. The semiconductor device as claimed in claim 1, wherein the sidewall of the upper portion of the first conductive pattern structure has a first slope with respect to the upper surface of the substrate, and
wherein a sidewall of the second conductive pattern structure has a second slope greater than the first slope with respect to the upper surface of the substrate.

8. The semiconductor device as claimed in claim 1, wherein a width of a lower portion of the conductive pattern structure is substantially the same as that of the second conductive pattern structure.

9. The semiconductor device as claimed in claim 1, wherein the etch stop layer includes silicon nitride (SiNₓ) or silicon carbonitride (SiCN).

10. The semiconductor device as claimed in claim 1, wherein the insulation layer includes silicon oxide.

11. The semiconductor device as claimed in claim 1, wherein the first conductive pattern structure includes a first conductive pattern and a first barrier pattern covering a lower surface and a sidewall of the first conductive pattern, and the second conductive pattern structure includes a second conductive pattern and a second barrier pattern covering a sidewall of the second conductive pattern.

12. A semiconductor device, comprising:
a conductive structure on a substrate;
an etch stop layer on the conductive structure;
an insulation layer on the etch stop layer; and
a contact plug extending through the etch stop layer and the insulation layer in a vertical direction substantially perpendicular to an upper surface of the substrate, and contacting the conductive structure,
wherein the contact plug includes a protrusion portion at least at a central portion thereof in the vertical direction, the protrusion portion protruding in a horizontal direction substantially parallel to the upper surface of the substrate.

13. The semiconductor device as claimed in claim 12, wherein the protrusion portion is formed not only at the central portion but also at a lower portion thereof.

14. The semiconductor device as claimed in claim 12, wherein a lower portion of the contact plug includes a sidewall having a constant slope with respect to the upper surface of the substrate.

15. The semiconductor device as claimed in claim 12, wherein an upper portion of the contact plug includes a sidewall having a constant slope with respect to the upper surface of the substrate.

16. The semiconductor device as claimed in claim 12, wherein each of sidewalls of an upper portion and a lower portion of the contact plug is substantially perpendicular to the upper surface of the substrate.

17. A semiconductor device, comprising:
an insulating interlayer on a substrate, the insulating interlayer containing a conductive line therein;
an etch stop layer on the conductive line and the insulating interlayer;
an insulation layer on the etch stop layer;
a contact plug extending through the etch stop layer and the insulation layer and contacting the conductive line;
a lower electrode on the contact plug;
an MTJ structure on the lower electrode; and
an upper electrode on the MTJ structure,
wherein the contact plug includes first and second conductive pattern structures, a width of an upper surface of the first conductive pattern structure is greater than that of a lower surface of the second conductive pattern structure, and at least an upper portion of the first conductive pattern structure has a sidewall not perpendicular but inclined to an upper surface of the substrate.

18. The semiconductor device as claimed in claim 17, wherein the width of the upper surface of the first conductive pattern structure is greater than that of a lower surface of the first conductive pattern structure.

19. The semiconductor device as claimed in claim 17, wherein the sidewall of the upper portion of the first conductive pattern structure has a first slope with respect to the upper surface of the substrate, and
wherein a sidewall of a lower portion of the first conductive pattern structure has a second slope greater than the first slope with respect to the upper surface of the substrate.

20. The semiconductor device as claimed in claim 17, wherein the etch stop layer includes silicon nitride (SiNₓ) or silicon carbonitride (SiCN), and the insulation layer includes silicon oxide.
